(19) United States
(12) Patent Application Publication
(10) Pub. No.: US 2022/0363549 A1
(43) Pub. Date: Nov. 17, 2022

(54) AMORPHOUS SILICON FORMING COMPOSITION AND METHOD FOR PRODUCING AMORPHOUS SILICON FILM USING SAME

(71) Applicant: Merck Patent GmbH, Darmstadt (DE)

(72) Inventors: Naoko NAKAMOTO, Kalegawa-shi (JP); Hideyuki TAKAGISH, Kalegawa-shi (JP); Takashi FUJIWARA, Kalegawa-shi (JP); Atsuhiko SATO, Kalegawa-shi (JP)

(21) Appl. No.: 17/778,113

(22) PCT Filed: Nov. 18, 2020
(86) PCT No.: PCT/EP2020/082484

§ 371 Date: May 19, 2022

(30) Foreign Application Priority Data
Nov. 21, 2019 (JP) 2019-210377

(51) Int. Cl. C01B 33/021; C08G 77/60; C09D 1/00; C07F 7/02; H01L 21/3205

(52) U.S. Cl. CPC C01B 33/021; C08G 77/60; C09D 1/00; C07F 7/025; H01L 21/32055

(57) ABSTRACT

To provide an amorphous silicon forming composition, which has high affinity with a substrate. An amorphous silicon forming composition comprising a polysilane having an amino group; and a solvent.

### BACKGROUND OF THE INVENTION

### Technical Field

The present invention relates to an amorphous silicon forming composition comprising a polysilane and a solvent, and a method for producing an amorphous silicon film using the same.

### Background Art

Electronic devices, especially semiconductor devices, comprise thin films such as semiconductor films, insulating films, and conductive films. Silicon films are used as a semiconductor film, an etching mask when processing an insulating film, and a sacrifice film when manufacturing a metal gate.

As a method for forming the amorphous silicon film and polycrystalline silicon, a chemical vapor deposition method (CVD method), a vapor deposition method, a sputtering method, and the like are used. In the advanced node, when the CVD process is used excessive growth for narrow trenches is caused, so that repeated etching and CVD are required. A film formation by applying a liquid composition comprising a silicon-containing polymer and baking the coating is performed. As a silicon-containing polymer, hydrogenated polysilane is known. However, the affinity of the liquid composition comprising the hydrogenated polysilane with a substrate is low. The case in which a film can be formed using this is very limited.

### PRIOR ART DOCUMENTS

### Patent Documents

[Patent document 1] JP 2013-43932 A
[Patent Document 2] JP H6-192429 A

### SUMMARY OF THE INVENTION

### Problems to be Solved by the Invention

The present invention has been made based on the background art as described above and provides an amorphous silicon forming composition, which has high affinity with a substrate. The amorphous silicon film formed using this composition is resistant to hydrofluoric acid and can be removed with an aqueous alkaline solution.

### Means for Solving the Problems

The amorphous silicon forming composition according to the present invention comprises:

a polysilane represented by formula (I):

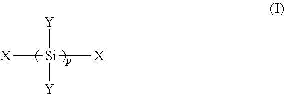

wherein

p is a number of 5 to 1,000,

X is each independently selected from the group consisting of a hydrogen atom, a halogen atom, and substituted or unsubstituted amino group,

Y is each independently selected from the group consisting of a single bond, a hydrogen atom, a halogen atom, —SiZ₃, and substituted or unsubstituted amino group, where neither of Y which are bonded to adjacent silicon atoms is a single bond,

Z is each independently selected from the group consisting of a single bond, a hydrogen atom, and a halogen atom,

when Y or Z is a single bond, the single bond with another single bond connects silicon atoms to which the single bonds are bonded,
provided that one or more of all X and Y is substituted or unsubstituted amino group; and a solvent.

The method for producing the amorphous silicon film according to the present invention comprises:

applying above mentioned amorphous silicon forming composition above a substrate to form a coating film; and

heating the coating film in a non-oxidizing atmosphere.

The method for manufacturing an electronic device according to the present invention comprises the above mentioned method for producing amorphous silicon.

### Effects of the Invention

According to the present invention, an amorphous silicon forming composition, which has high affinity with a substrate can be provided. The amorphous silicon film formed using this composition is resistant to hydrofluoric acid and can be removed with an aqueous alkaline solution.

### DETAILED DESCRIPTION OF THE INVENTION

### Mode for Carrying Out the Invention

Embodiments of the present invention are described below in detail. Hereinafter, symbols, units, abbreviations, and terms have the following meanings in the present specification unless otherwise specified.

In the present specification, when numerical ranges are indicated using “to”, they include both end points, and the units thereof are common. For example, 5 to 25 mol % means 5 mol % or more and 25 mol % or less.

In the present specification, the hydrocarbon means one including carbon and hydrogen, and optionally including oxygen or nitrogen. The hydrocarbyl group means a monovalent or divalent or higher valent hydrocarbon.

In the present specification, the aliphatic hydrocarbon means a linear, branched or cyclic aliphatic hydrocarbon, and the aliphatic hydrocarbon group means a monovalent or divalent or higher valent aliphatic hydrocarbon. The aromatic hydrocarbon means a hydrocarbon comprising an aromatic ring which may optionally not only comprise an aliphatic hydrocarbon group as a substituent but also be condensed with an alicycle. The aromatic hydrocarbon group means a monovalent or divalent or higher valent aromatic hydrocarbon. These aliphatic hydrocarbon groups and aromatic hydrocarbon groups optionally contain fluorine, oxy, hydroxy, amino, carbonyl, or silyl and the like. Further, the aromatic ring means a hydrocarbon comprising a conjugated unsaturated ring structure, and the alicycle means a hydrocarbon comprising a ring structure but no conjugated unsaturated ring structure.

In the present specification, the alkyl means a group obtained by removing any one hydrogen from a linear or branched, saturated hydrocarbon and includes a linear alkyl and branched alkyl, and the cycloalkyl means a group obtained by removing one hydrogen from a saturated hydrocarbon comprising a cyclic structure and includes a linear or branched alkyl in the cyclic structure as a side chain, if necessary.

In the present specification, the aryl means a group obtained by removing any one hydrogen from an aromatic hydrocarbon. The alkylene means a group obtained by removing any two hydrogen from a linear or branched, saturated hydrocarbon. The arylene means a hydrocarbon group obtained by removing any two hydrogen from an aromatic hydrocarbon.

In the present specification, the description such as “C_{x-y}”, “Cₓ-C_{y}” and “Cₓ” means the number of carbons in the molecule or substituent group. For example, C₁₋₆ alkyl means alkyl having 1 to 6 carbons (such as methyl, ethyl, propyl, butyl, pentyl and hexyl). Further, the fluoroalkyl as used in the present specification refers to one in which one or more hydrogen in alkyl is replaced with fluorine, and the fluoroaryl is one in which one or more hydrogen in aryl are replaced with fluorine.

In the present specification, when a polymer comprises plural types of repeating units, these repeating units copolymerize. These copolymerizations can be any of alternating copolymerization, random copolymerization, block copolymerization, graft copolymerization, or any mixture thereof.

In the present specification, “%” represents mass % and “ratio” represents ratio by mass.

In the present specification, Celsius is used as the temperature unit. For example, 20 degrees means 20 degrees Celsius.

<Amorphous Silicon Forming Composition>

The amorphous silicon forming composition according to the present invention (hereinafter referred to as the composition) comprises a polysilane having a certain structure; and a solvent.

(a) polysilane

The polysilane used for the present invention is represented by formula (I):

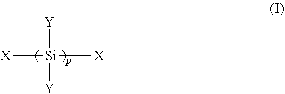

wherein

p is a number of 5 to 1,000, preferably 10 to 500,

X is each independently selected from the group consisting of a hydrogen atom, a halogen atom, and substituted or unsubstituted amino group, preferably selected from the group consisting of a hydrogen atom and substituted or unsubstituted amino group,

Y is each independently selected from the group consisting of a single bond, a hydrogen atom, a halogen atom, —SiZ₃, and substituted or unsubstituted amino group, preferably selected from the group consisting of a single bond, a hydrogen atom, and substituted or unsubstituted amino group,

Z is each independently selected from the group consisting of a single bond, a hydrogen atom, and a halogen atom, preferably a single bond or a hydrogen atom. Preferably, one of three Z which are bonded to the same silicon atom is a single bond and the others are a hydrogen atom or a halogen atom (preferably a hydrogen atom).

When Y or Z is a single bond, the single bond with another single bond contained in formula (I) connects silicon atoms to which the single bonds are bonded. At this time, a ring having silicon atoms is formed. Neither of Y which are bonded to adjacent silicon atoms is a single bond. That is, silicons are not connected by a double bond.

Provided that one or more of all X and Y is substituted or unsubstituted amino group, preferably one or more of Y is amino group.

The polysilane used for the present invention can have a ring structure or no ring structure. When none of X and Y is a single bond in formula (I), the polysilane do not have a ring structure. In a suitable embodiment of the present invention, the polysilane has no ring structure.

When the polysilane has a ring structure, the polysilane can have two or more ring structures in one polysilane molecule. The ring structure is preferably a five membered ring or a six membered ring, more preferably a six membered ring.

Preferably, the amino group is the group represented by the formula (A) or (B):

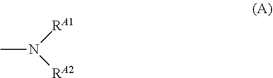

wherein R^{A1} and R^{A2} are each independently a hydrogen atom or C₁₋₁₂ alkyl group. Preferably, R^{A1} and R^{A2} are each independently methyl group, ethyl group, butyl group, propyl group, pentyl group, hexyl group, heptyl group, octyl group, or nonyl group;

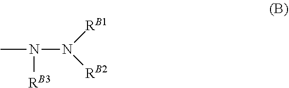

wherein

R^{B1} and R^{B2} are each independently a hydrogen atom or C₁₋₁₂ alkyl group, and

R^{B3} is independently a hydrogen atom or C₁₋₄ alkyl group. Preferably, R^{B1} and R^{B2} are each independently methyl group or ethyl group, and R^{B3} is a hydrogen atom or methyl group.

More preferably, the amino group is dialkylamino group. Further preferably, the amino group is selected from the group consisting of di-n-butylamino group, diisobutylamino group, di-sec-butylamino group, diisopropylamino group, di-n-propylamino group, diethylamino group and dimethylamino group.

Examples of the polysilane represented by formula (I) are following:

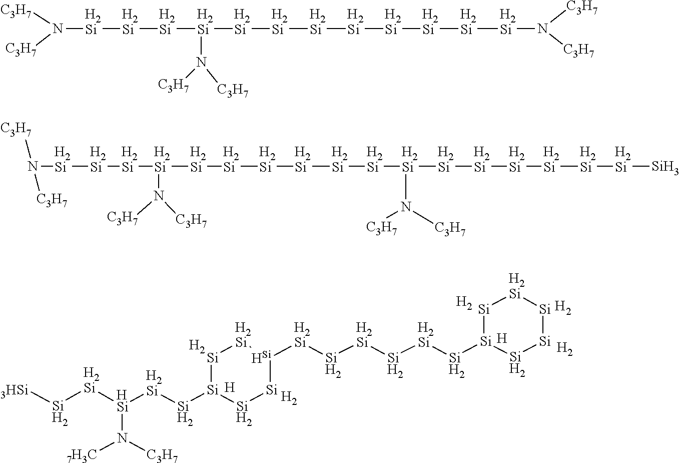

The polysilane represented by the formula (I) has amino group and no Si—C bond. Although not to be bound by theory, it is considered that hydrophilicity of the polysilane is improved by amino group, and the polysilane have an affinity to hydroxy group of the surface of the substrate and thus coating properties can be improved. Further, it is considered that no Si—C bond raises high solubility of the formed film in alkali solution and enables the film to be etched by alkali solution.

The ratio of the number of N atoms containing in the molecule to that of Si atoms containing in the polysilane molecule (in the present invention, referred to as “N/Si ratio”) is preferably 0.1 to 40%, more preferably 0.3 to 35%. When N/Si ratio is less than 0.1%, no effect of amino group can be observed. When N/Si ratio is more than 40%, precipitation can be observed due to compatibility of condensed polysilane with amine.

The N/Si ratio of the molecule can be calculated, for example, from an element ratio obtained by an elemental analysis by Rutherford backscattering spectroscopy of a film formed using the polysilane. Specifically, it can be measured as described below. The polysilane solution comprising the polysilane used for the present invention and a solvent is spin-coated on a 4 inch wafer at a rotation speed of 1,000 rpm using a spin coater (Spin Coater 1HDX2 (trade name), manufactured by Mikasa Co., Ltd.) under a nitrogen atmosphere. The obtained coating film is baked at 240° C. for 10 minutes under a nitrogen atmosphere. The baked film is subjected to elemental analysis by Rutherford backscattering spectrometry using Pelletron 3SDH (trade name, manufactured by National Electrostatics Corporation), whereby a ratio of the number of atoms is measured.

Because of the solubility in the solvent, the planarization of the formed film and the adhesion to the substrate, the mass average molecular weight of the polysilane used for the present invention is preferably 200 to 25,000, and more preferably 300 to 15,000. The mass average molecular weight is a mass average molecular weight in terms of polystyrene, and it can be measured by gel permeation chromatography based on polystyrene.

Although the method for producing the polysilane used for the present invention is not particularly limited, the production method, for example, comprises:

(A) a step of irradiating a cyclic polysilane comprising 5 or more silicon with light;
(B) a step of preparing a mixture comprising an amine; and
(C) a step of irradiating the mixture with light.

Hereinafter, an example of the production method is described for each step.

(A) Step of irradiating cyclic polysilane comprising 5 or more silicon with light

The cyclic polysilane comprising 5 or more silicon (hereinafter referred to as “cyclic polysilane”) can be freely selected unless it impairs the effect of the present invention. These are either inorganic compounds or organic compounds and can be linear, branched, or partially having a cyclic structure.

Preferably, the cyclic polysilane is represented by the following formula (I′):

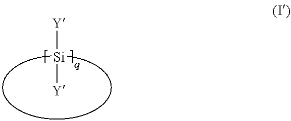

wherein Y′ is each independently a hydrogen atom or a halogen atom, and q is a number of 5 or more.

Preferably, q is 5 to 8, more preferably 5 or 6.

Examples of the preferred cyclic polysilane include silyl cyclopentasilane, silyl cyclohexasilane, disilyl cyclohexasilane, cyclopentasilane and cyclohexasilane, preferably cyclopentasilane or cyclohexasilane.

The wavelength in the step (A) preferably comprises at least a wavelength of 172 to 405 nm, more preferably 282 to 405 nm. The irradiation intensity is preferably 10 to 250 mW/cm², more preferably 50 to 150 mW/cm², and the irradiation time is preferably 30 to 300 seconds, more preferably 50 to 200 seconds.

Since cyclopentasilane or cyclohexasilane is a liquid at room temperature, light can be irradiated to the cyclic polysilane being in its liquid state while stirring. In addition, when cyclosilane is a solid, it can be dissolved in an appropriate solvent and irradiated with light while stirring.

It is considered that some or all of the cyclic polysilane undergo ring-opening reaction by the light irradiation in this step.

(B) Step of preparing mixture comprising an amine

The amine is selected from primary to tertiary amine. Preferably, it is represented by formula (A′) or (B′):

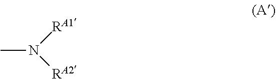

wherein R^{A1′} and R^{A2′} are each independently a hydrogen atom or C₁₋₁₂ alkyl group. Preferably, R^{A1′} and R^{A2′} are each independently methyl group, ethyl group, butyl group, propyl group, pentyl group, hexyl group, heptyl group, octyl group, or nonyl group;

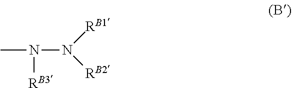

wherein

R^{B1′} and R^{B2′} are each independently a hydrogen atom or C₁₋₁₂ alkyl group, and

R^{B3′} is independently a hydrogen atom or C₁₋₄ alkyl group. Preferably, R^{B1′} and R^{B2′} are each independently methyl group or ethyl group, and R^{B3′} is a hydrogen atom or methyl group.

More preferably, the amine is dialkylamine. Further preferably, the amine is selected from the group consisting of di-n-butylamine, diisobutylamine, di-sec-butylamine, diisopropylamine, di-n-propylamine, diethylamine and dimethylamine.

When the cyclic polysilane irradiated with light is a liquid at room temperature, the amine is added to it and then stirred to prepare a mixture. When the cyclic polysilane irradiated with light is a solid at room temperature, the amine can be dissolved into a proper solvent and then added to the cyclic polysilane irradiated with light and then stirred to prepare a mixture.

(C) Step of irradiating the mixture with light

It is considered that addition of the amine to the polysilane and condensation of the polysilane each other occur by light irradiation in this step.

The wavelength of irradiation light at this time preferably includes at least a wavelength of 172 to 405 nm, more preferably 282 to 405 nm. The irradiation intensity is preferably 10 to 250 mW/cm², more preferably 50 to 150 mW/cm², and the irradiation time is preferably 5 to 100 minutes, more preferably 5 to 60 minutes. The irradiation energy is preferably 3 to 1,500 J, more preferably 25 to 500 J.

The above-mentioned steps (A), (B), and (C) are preferably carried out in a non-oxidizing atmosphere.

(b) Solvent

The composition according to the present invention comprises a solvent. The solvent is selected from those which uniformly dissolve or disperse each component contained in the composition. Specifically, examples of the solvent include ethylene glycol monoalkyl ethers, such as ethylene glycol monomethyl ether, ethylene glycol monoethyl ether, ethylene glycol monopropyl ether and ethylene glycol monobutyl ether; diethylene glycol dialkyl ethers, such as diethylene glycol dimethyl ether, diethylene glycol diethyl ether, diethylene glycol dipropyl ether and diethylene glycol dibutyl ether; ethylene glycol alkyl ether acetates, such as methyl cellosolve acetate and ethyl cellosolve acetate; propylene glycol monoalkyl ethers, such as propylene glycol monomethyl ether (PGME) and propylene glycol monoethyl ether; propylene glycol alkyl ether acetates such as propylene glycol monomethyl ether acetate (PGMEA), propylene glycol monoethyl ether acetate and propylene glycol monopropyl ether acetate; aromatic hydrocarbons, such as benzene, toluene, xylene and mesitylene; ketones, such as methyl ethyl ketone, acetone, methyl amyl ketone, methyl isobutyl ketone and cyclohexanone; alcohols, such as isopropanol and propanediol; and alicyclic hydrocarbons, such as cyclooctane and decalin. Preferred are cyclooctane, toluene, decalin and mesitylene.

These solvents can be used alone or in combination of two or more of any of these.

In order to homogeneously dissolve polysilane, the relative dielectric constant of the solvent is preferably 3.0 or less, more preferably 2.5 or less on the basis of the value described in “Solvent Handbook, 1st Edition”, Kodansha Scientific.

Although the mixing ratio of the solvent varies depending on the coating method and the film thickness after coating, the ratio (solid content ratio) of the compounds other than the solvent is 1 to 96 mass %, and preferably 2 to 60 mass %.

The composition used in the present invention essentially comprises the above-mentioned (a) and (b), but if necessary, further compounds can be combined. The materials which can be combined are described below. The components other than (a) and (b) contained in the whole composition are preferably 10% or less, and more preferably 5% or less, based on the total mass.

(c) Optional Components

In addition, the composition according to the present invention can contain optional components, if needed. Such optional components include, for example, surfactants.

Surfactants are preferably used because they can improve the coating properties. The surfactants which can be used in the siloxane composition of the present invention include nonionic surfactants, anionic surfactants, amphoteric surfactants, and the like.

Examples of the nonionic surfactant include, polyoxyethylene alkyl ethers, such as polyoxyethylene lauryl ether, polyoxyethylene oleyl ether and polyoxyethylene cetyl ether; polyoxyethylene fatty acid diester; polyoxyethylene fatty acid monoester; polyoxyethylene polyoxypropylene block polymer; acetylene alcohol; acetylene glycols; acetylene alcohol derivatives, such as polyethoxylate of acetylene alcohol; acetylene glycol derivatives, such as polyethoxylate of acetylene glycol; fluorine-containing surfactants, for example, FLUORAD (trade name, manufactured by 3M Japan Limited), MEGAFAC (trade name: manufactured by DIC Cooperation), SURFLON (trade name, manufactured by AGC Inc.); or organosiloxane surfactants, for example, KP341 (trade name, manufactured by Shin-Etsu Chemical Co., Ltd.), and the like. Examples of said acetylene glycol include 3-methyl-1-butyne-3-ol, 3-methyl-1-pentyn-3-ol, 3,6-dimethyl-4-octyne-3,6-diol, 2,4,7,9-tetramethyl-5-decyne-4,7-diol, 3,5-dimethyl-1-hexyne-3-ol, 2,5-dimethyl-3-hexyne-2,5-diol, 2,5-dimethyl-2,5-hexane-diol, and the like.

Further, examples of the anionic surfactant include ammonium salt or organic amine salt of alkyl diphenyl ether disulfonic acid, ammonium salt or organic amine salt of alkyl diphenyl ether sulfonic acid, ammonium salt or organic amine salt of alkyl benzene sulfonic acid, ammonium salt or organic amine salt of polyoxyethylene alkyl ether sulfuric acid, ammonium salt or organic amine salt of alkyl sulfuric acid, and the like.

Further, examples of the amphoteric surfactant include 2-alkyl-N-carboxymethyl-N-hydroxyethyl imidazolium betaine, lauric acid amide propyl hydroxysulfone betaine, and the like.

These surfactants can be used alone or in combination of two or more of any of these, and the mixing ratio thereof is usually 50 to 10,000 ppm, and preferably 100 to 5,000 ppm, based on the total mass of the composition.

<Method for Producing Amorphous Silicon Film>

The method for producing an amorphous silicon film according to the present invention comprises applying the above amorphous silicon forming composition above a substrate to form a coating film and heating the coating film in a non-oxidizing atmosphere.

In the present invention, the “above a substrate” includes the case where the composition is applied directly on a substrate and the case where the composition is applied on a substrate via one or more intermediate layer.

The method for coating the composition above a substrate surface can be freely selected from known methods, such as spin coating, dip coating, spray coating, transfer coating, roll coating, bar coating, brush coating, doctor coating, flow coating, slit coating, and the like. Moreover, as a substrate on which the composition is coated, suitable substrates, such as a silicon substrate, a glass substrate, a resin film, can be used. Various semiconductor elements and the like can be formed on these substrates, if necessary. When the substrate is a film, gravure coating can be also used. A drying step can also be provided separately after coating a film if desired. Further, by repeating the coating step once or twice or more as needed, the film thickness of the coating film to be formed can be made as desired.

After forming a coating film of the composition according to the present invention, pre-baking (heating treatment) of the coating film can be carried out in order to dry the coating film and reduce the residual amount of the solvent. The pre-baking process can be carried out in a non-oxidizing atmosphere preferably at a temperature of 80 to 200° C., in the case of a hot plate for 10 to 300 seconds and in the case of a clean oven for 1 to 30 minutes. In the present invention, the non-oxidizing atmosphere means an atmosphere having an oxygen concentration of 1 ppm or less and a dew point of −76° C. or lower. Preferably, a gas atmosphere of N₂, Ar, He, Ne, H₂, or a mixture of two or more of any of these is used.

Thereafter, the coating film is heated to cure, thereby forming an amorphous silicon film. So long as it is a temperature at which a coating film having appropriate crystallinity can be obtained, the heating temperature in this heating step is not particularly limited and can be freely determined. However, chemical resistance of the cured film sometimes become insufficient or dielectric constant of the cured film sometimes become increased. From this point of view, for the heating temperature, a relatively high temperature is generally selected. In order to accelerate the curing reaction and obtain a sufficiently cured film, the curing temperature is preferably 200° C. or higher, and more preferably 300° C. or higher. In general, the curing temperature is preferably 1,000° C. or lower, because crystallization of amorphous silicon proceeds. Further, the heating time is not particularly limited and is generally 10 minutes to 24 hours, and preferably 0.001 seconds to 24 hours. Flash annealing can be used for the heating. In addition, this heating time is the time after the temperature of the coating film reaches a desired heating temperature. Normally, it takes several seconds to several hours until the coating film reaches a desired temperature from the temperature before heating. Further, it is preferred that the atmosphere at the time of curing is a non-oxidizing atmosphere.

After forming a coating film using the composition according to the present invention, before said cure step, electron beam irradiation or light irradiation to the coating film can be further carried out. It is possible to suppress the decrease in film thickness in the curing step by electron beam irradiation or light irradiating to the coating film. The light irradiation is preferably to irradiate light having the wavelength of 172 to 436 nm, and more preferably 248 to 405 nm. The irradiation intensity is preferably 10 to 800 mW/cm², and more preferably 40 to 600 mW/cm², and the irradiation time is preferably 30 to 3,500 seconds, and more preferably 50 to 3,000 seconds.

The film thickness of the obtained cured film is not particularly limited, but preferably 5 nm to 1 μm, more preferably 10 to 500 nm.

The crystallinity of the formed cured film can be evaluated by X-ray diffraction (XRD). Here, if no diffraction peak of crystalline Si is observed after curing, it is confirmed that the cured film is made of amorphous silicon.

Applications of the amorphous silicon film is not particularly limited. Since the amorphous silicon film is easily dissolved in an aqueous alkaline solution, it can be used as a sacrifice film. The aqueous alkaline solution can be properly selected depending on the formed cured film. To be used for the etching is not particularly limited, and examples thereof include aqueous potassium hydroxide solution, aqueous sodium hydroxide solution, ammonia water, aqueous tetramethylammonium hydroxide (TMAH) solution and the like. For example, the etching rate for a 10 mass % aqueous potassium hydroxide solution at room temperature (20 to 30° C.) is preferably 0.1 to 1,000 Å/min, and more preferably 10 to 1,000 Å/min.

On the other hand, this amorphous silicon film is resistant to a hydrofluoric acid. Specifically, the etching rate to a 0.5 mass % hydrofluoric acid aqueous solution at room temperature is preferably 0 to 200 Å/min, and more preferably 0 to 50 Å/min.

The resistance to alkaline solution can be controlled by adjusting the conditions of the producing the amorphous silicon film. By raising the heating temperature or lengthening the heating time in forming the amorphous silicon film, the resistance to alkaline solution can be improved.

The method for producing electronic device according to the present invention comprises above mentioned method. The method for producing electronic device further comprises the step in which the amorphous silicon film is removed with such as an aqueous alkaline solution, as mentioned above.

Hereinafter, the present invention is explained with reference to Examples. These Examples are for explanation and are not intended to limit the scope of the present invention.

In the following description, “part” is on a mass basis unless otherwise specified.

The synthesis of the polysilane and preparing step of the composition in the following Examples and Comparative Examples are all carried out in a glove box controlled to have an oxygen concentration of 0.1 ppm or less and a dew point temperature of −76.0° C. or less under an inert gas atmosphere.

### Example 1

A stirrer tip is placed in a 6 mL screw tube, and 250.18 mg of cyclohexasilane is added thereto and stirred using a stirrer. 4.9 J/cm² of ultraviolet ray having a wavelength of 365 nm using a LED lamp as a light source is irradiated. After the ultraviolet ray irradiation, 35.08 mg of diisopropylamine is added thereto and stirred using a stirrer. While continuing to stir, 4.9 J/cm² of ultraviolet ray having a wavelength of 365 nm using a LED lamp as a light source is irradiated to form a polysilane. After the ultraviolet ray irradiation, cyclooctane is added so as to make the concentration of the polysilane becomes 19 mass %, and after stirring for 3 minutes, filtration is carried out using a 0.2 μm PTFE filter (DISMIC-13JP, manufactured by Advantec), to obtain an amorphous silicon forming composition A.

The mass average molecular weight of the synthesized polysilane is 880 and N/Si ratio measured by Rutherford backscattering spectroscopy is 4.2%.

The amorphous silicon forming composition A is coated on a Si substrate in a nitrogen atmosphere using a spin coater (Spin Coater 1HDX2 (trade name), manufactured by Mikasa Co., Ltd.) to form a coating film. The obtained coating film is heated at 400° C. for 15 minutes on a hot plate to obtain an amorphous silicon film. When the obtained amorphous silicon film is measured by secondary ion mass spectrometry (SIMS), the result thereof is as follows: Si: 94.95 mass %, O: 0.52 mass %, N: 1.98 mass %, and C: 2.55 mass %. The diffraction peak of crystalline Si is not observed from the measurement of XRD, by which it is confirmed that the silicon is amorphous silicon.

The film thickness of the obtained amorphous silicon film is 33.3 nm, and the refractive index (633 nm) thereof is 3.22.

Further, the obtained amorphous silicon film is etched in a 10 mass % potassium hydroxide aqueous solution, and the etching rate is 55 nm/min. On the other hand, by the etching using 0.5 mass % hydrofluoric acid aqueous solution, the etching rate is 0.3 nm/min, which shows that the film has HF resistance.

### Example 2

A stirrer tip is placed in a 6 mL screw tube, and 240.56 mg of cyclohexasilane is added thereto and stirred using a stirrer. While continuing to stir, 4.9 J/cm² of ultraviolet ray having a wavelength of 365 nm using a LED lamp as a light source is irradiated. After the ultraviolet ray irradiation, 19.95 mg of di-n-butylamine is added thereto and 14.7 J/cm² of ultraviolet ray having a wavelength of 365 nm using a LED lamp as a light source is irradiated, and then stirred for 30 minutes at 40° C. to form a polysilane. Thereafter, cyclooctane is added so as to make the concentration of the polysilane becomes 19 mass %, and after stirring for 3 minutes, filtration is carried out using a 0.2 μm PTFE filter to obtain an amorphous silicon forming composition B.

The mass average molecular weight of the synthesized polysilane is 1,250 and N/Si ratio measured by Rutherford backscattering spectroscopy is 1.9%.

The amorphous silicon forming composition B is coated on a Si substrate in a nitrogen atmosphere using a spin coater to form a coating film. The obtained coating film is heated at 400° C. for 15 minutes on a hot plate to obtain an amorphous silicon film. When the obtained amorphous silicon film is measured by secondary ion mass spectrometry, the result thereof is as follows: Si: 94.70 mass %, O: 0.46 mass %, N: 1.53 mass %, and C: 3.31 mass %. The diffraction peak of crystalline Si is not observed from the measurement of XRD, by which it is confirmed that the silicon is amorphous silicon.

The film thickness of the obtained amorphous silicon film is 92.0 nm, and the refractive index (633 nm) thereof is 3.68.

Further, the obtained amorphous silicon film is etched in a 10 mass % potassium hydroxide aqueous solution, and the etching rate is 60 nm/min. On the other hand, by the etching using 0.5 mass % hydrofluoric acid aqueous solution, the etching rate is 0.2 nm/min, which shows that the film has HF resistance.

### Example 3

A stirrer tip is placed in a 6 mL screw tube, and 249.96 mg of cyclohexasilane is added thereto and stirred using a stirrer. While continuing to stir, 4.9 J/cm² of ultraviolet ray having a wavelength of 365 nm using a LED lamp as a light source is irradiated. After the ultraviolet ray irradiation, 35.98 mg of 1,1,2-trimethylhydrazine is added thereto. Then, while continuing to stir, 14.7 J/cm² of ultraviolet ray having a wavelength of 365 nm using a LED lamp as a light source is irradiated to form a polysilane. Thereafter, cyclooctane is added so as to make the concentration of the polysilane becomes 19 mass %, and after stirring for 3 minutes, filtration is carried out using a 0.2 μm PTFE filter to obtain an amorphous silicon forming composition C.

The mass average molecular weight of the synthesized polysilane is 1,380 and N/Si ratio measured by Rutherford backscattering spectroscopy is 11.7%.

The amorphous silicon forming composition C is coated on a Si substrate in a nitrogen atmosphere using a spin coater to form a coating film. The obtained coating film is heated at 400° C. for 15 minutes on a hot plate to obtain an amorphous silicon film. The diffraction peak of crystalline Si is not observed from the measurement of XRD, by which it is confirmed that the silicon is amorphous silicon.

The film thickness of the obtained amorphous silicon film is 63.7 nm, and the refractive index (633 nm) thereof is 3.67.

Further, the obtained amorphous silicon film is etched in a 10 mass % potassium hydroxide aqueous solution, and the etching rate is 32 nm/min. On the other hand, by the etching using 0.5 mass % hydrofluoric acid aqueous solution, the etching rate is 0.3 nm/min, which shows that the film has HF resistance.

### Example 4

A stirrer tip is placed in a 6 mL screw tube, and 250.31 mg of cyclohexasilane is added thereto and stirred using a stirrer. While continuing to stir, 3.3 J/cm² of ultraviolet ray having a wavelength of 365 nm using a LED lamp as a light source is irradiated. After the ultraviolet ray irradiation, 7.16 mg of diisopropylamine is added thereto. While continuing to stir, 14.8 J/cm² of ultraviolet ray having a wavelength of 365 nm using a LED lamp as a light source is irradiated to form a polysilane. Thereafter, cyclooctane is added so as to make the concentration of the polysilane becomes 19 mass %, and after stirring for 3 minutes, filtration is carried out using a 0.2 μm PTFE filter to obtain an amorphous silicon forming composition D.

The mass average molecular weight of the synthesized polysilane is 1,630 and N/Si ratio measured by Rutherford backscattering spectroscopy is 0.85%.

The amorphous silicon forming composition D is coated on a Si substrate in a nitrogen atmosphere using a spin coater to form a coating film. The obtained coating film is heated at 400° C. for 15 minutes on a hot plate to obtain an amorphous silicon film. The diffraction peak of crystalline Si is not observed from the measurement of XRD, by which it is confirmed that the silicon is amorphous silicon.

The film thickness of the obtained amorphous silicon film is 120.2 nm, and the refractive index (633 nm) thereof is 3.80.

Further, the obtained amorphous silicon film is etched in a 10 mass % potassium hydroxide aqueous solution, and the etching rate is 62 nm/min. On the other hand, by the etching using 0.5 mass % hydrofluoric acid aqueous solution, the etching rate is 0.2 nm/min, which shows that the film has HF resistance.

### Example 5

A stirrer tip is placed in a 6 mL screw tube, and 250.13 mg of cyclohexasilane is added thereto and stirred using a stirrer. While continuing to stir, 3.3 J/cm² of ultraviolet ray having a wavelength of 365 nm using a LED lamp as a light source is irradiated. After the ultraviolet ray irradiation, 326.5 mg of diisopropylamine is added thereto. While continuing to stir, 14.8 J/cm² of ultraviolet ray having a wavelength of 365 nm using a LED lamp as a light source is irradiated to form a polysilane. Thereafter, cyclooctane is added so as to make the concentration of the polysilane becomes 19 mass %, and after stirring for 3 minutes, filtration is carried out using a 0.2 μm PTFE filter to obtain an amorphous silicon forming composition E.

The mass average molecular weight of the synthesized polysilane is 1,040 and N/Si ratio measured by Rutherford backscattering spectroscopy is 39%.

The amorphous silicon forming composition E is coated on a Si substrate in a nitrogen atmosphere using a spin coater to form a coating film. The obtained coating film is heated at 400° C. for 15 minutes on a hot plate to obtain an amorphous silicon film. The diffraction peak of crystalline Si is not observed from the measurement of XRD, by which it is confirmed that the silicon is amorphous silicon.

The film thickness of the obtained amorphous silicon film is 28.7 nm, and the refractive index (633 nm) thereof is 3.82.

Further, the obtained amorphous silicon film is etched in a 10 mass % potassium hydroxide aqueous solution, and the etching rate is 28 nm/min. On the other hand, by the etching using 0.5 mass % hydrofluoric acid aqueous solution, the etching rate is 0.2 nm/min, which shows that the film has HF resistance.

### Comparative Example 1

A stirrer tip is placed in a 6 mL screw tube, and 272 mg of cyclohexasilane is added thereto and stirring is carried out using a stirrer. 8.6 J/cm² of ultraviolet ray having the wavelength of 365 nm is irradiated using a mercury xenon lamp as a light source. After the irradiation, 98.4 J/cm² of ultraviolet ray having the wavelength of 365 nm is irradiated using a mercury xenon lamp as a light source and then it is stirred for 20 minutes. Thereafter, cyclooctane is added so as to make the solid content concentration become 19 mass % and stirring is carried out for 3 minutes. Then, filtration is performed using a 5.0 μm PTFE filter and 0.2 μm PTFE filter to obtain a comparative composition A.

The comparative composition A is coated on a Si substrate in a nitrogen atmosphere using a spin coater to try to form a coating film, but the comparison composition A is not able to be coated on the substrate and did not lead to film formation.

1.-11. (canceled)

12. An amorphous silicon forming composition comprising:
a polysilane represented by formula (I): 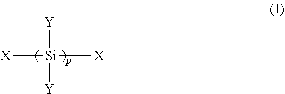
wherein
p is a number of 5 to 1,000,
X is each independently selected from the group consisting of a hydrogen atom, a halogen atom, and substituted or unsubstituted amino group,
Y is each independently selected from the group consisting of a single bond, a hydrogen atom, a halogen atom, —SiZ₃, and substituted or unsubstituted amino group, where neither of Y which are bonded to adjacent silicon atoms is a single bond,
Z is each independently selected from the group consisting of a single bond, a hydrogen atom, and a halogen atom,
when Y or Z is a single bond, the single bond with another single bond connects silicon atoms to which the single bonds are bonded,
provided that one or more of all X and Y is substituted or unsubstituted amino group; and
a solvent.

13. The composition according to claim 12, wherein the amino group is the group represented by the formula (A) or (B): 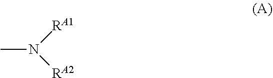
wherein R^{A1} and R^{A2} are each independently a hydrogen atom or C₁₋₁₂ alkyl group, 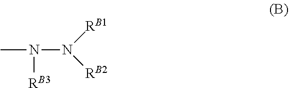
wherein
R^{B1} and R^{B2} are each independently a hydrogen atom or C₁₋₁₂ alkyl group, and
R^{B3} is independently a hydrogen atom or C₁₋₄ alkyl group.

14. The composition according to claim 12, wherein the amino group is dialkylamino group.

15. The composition according to claim 12, wherein the amino group is selected from the group consisting of di-n-butylamino group, diisobutylamino group, di-sec-butylamino group, diisopropylamino group, di-n-propylamino group, diethylamino group and dimethylamino group.

16. The composition according to a claim 12, wherein one or more Y is an amino group.

17. The composition according to claim 12, wherein the mass average molecular weight of the polysilane is 200 to 25,000 measured by ger permeation chromatography in terms of polystyrene.

18. The composition according to claim 12, wherein the ratio of the number of N atoms to the number of Si atoms containing in the polysilane molecule is 0.1 to 40%.

19. The composition according to a claim 12, wherein the relative dielectric constant of the solvent is 3.0 or less.

20. A method for producing an amorphous silicon film, comprising:
applying the composition according to claim 12 above a substrate to form a coating film; and
heating the coating film in a non-oxidizing atmosphere.

21. The method according to claim 20, wherein the heating is performed at 200 to 1,000° C.

22. An electronic device manufactured by comprising the method according to claim 20.
